(19) United States
(12) Patent Application Publication
(10) Pub. No.: US 2011/0117289 A1
(43) Pub. Date: May 19, 2011

(54) Deposition Apparatus and Deposition Method

(75) Inventors: Nobuhiro Hayashi, Kanagawa (JP); Yosuke Kobayashi, Kanagawa (JP); Takao Saitou, Kanagawa (JP); Masayuki Iijima, Kanagawa (JP); Isao Tada, Kanagawa (JP)

(73) Assignee: ULVAC, INC., Chigasaki-shi, Kanagawa (JP)

(21) Appl. No.: 12/808,391

(22) PCT Filed: Dec. 12, 2008
(86) PCT No.: PCT/JP2008/072686

§ 371 Date: Jun. 16, 2010

(30) Foreign Application Priority Data
Dec. 28, 2007 (JP) 2007-338570

(51) Int. Cl. C23C 16/02; B05C 13/00; B05C 11/00; C23C 16/448; C23C 16/50; C23C 16/455; C23C 16/458; C23C 14/34

(52) U.S. Cl. 427/534; 118/50; 118/723 R; 118/726; 427/569; 204/298.07; 204/192.1

(57) ABSTRACT

[Object] To provide a deposition apparatus and a deposition method that are capable of reducing an evacuation time in an evacuation system having a large condensing load to improve productivity.

[Solving Means] A deposition apparatus that forms a film on a plurality of base materials at the same time, includes a support unit including a support section that rotatably supports the plurality of base materials around a rotation shaft, a vacuum chamber including a cylindrical processing chamber that rotatably accommodates the support unit, deposition sources provided inside the vacuum chamber, a low temperature evacuation section including a low temperature condensation source provided opposed to an upper support member on an upper surface of the vacuum chamber, and auxiliary pumps.

### FIELD

The present invention relates to a batch-type deposition apparatus and a deposition method for forming films on a plurality of base materials at the same time.

### BACKGROUND

In the past, a batch-type deposition apparatus has been used for forming films on a plurality of base materials at the same time using a vacuum process (see, for example, Patent Document 1).

The deposition apparatus of this type opens a processing chamber each time predetermined deposition processes on base materials are completed to carry out the base materials on which the films have been formed from the processing chamber and carry in base materials on which films have not yet been formed to the processing chamber. In this carry-in/carry-out process, it is inevitable that an atmosphere in the processing chamber will be destructed, and particularly an exposure of the processing chamber to an air atmosphere cannot be avoided. Thus, a process of evacuating the processing chamber from an air atmosphere to a predetermined degree of vacuum is performed each time base materials are replaced in many apparatuses.
Patent Document 1: Japanese Patent Application Laid-open No. 2003-133284

### SUMMARY

### Problem to be Solved by the Invention

In recent years, there is an increasing demand to reduce an evacuation time in a processing chamber as much as possible in view of a reduction in downtime cost of an apparatus and an improvement of productivity. A vacuum evacuation performance mainly and largely depends on an evacuation performance of a vacuum pump. A vacuum evacuation system is often constituted of a plurality of vacuum pumps connected in series or in parallel, as well as a single vacuum pump. Especially in a process that requires relatively-high vacuum, a vacuum pump for low to middle vacuum and a vacuum pump for high vacuum are used in combination.

However, in an evacuation system in which a condensing load is large as in the case of evacuating an inside of a vacuum chamber from an air atmosphere to a high degree of vacuum, an original evacuation performance cannot be fully exerted in many cases even when a vacuum pump having a high evacuation ability is provided. As a result, there is a problem that the evacuation time cannot be reduced and productivity cannot be improved in a conventional batch-type deposition apparatus.

In view of the above problem, it is an object of the present invention to provide a deposition apparatus and a deposition method that are capable of reducing an evacuation time in an evacuation system having a large condensing load to improve productivity.

### Means for Solving the Problem

According to an embodiment of the present invention, there is provided a deposition apparatus that forms a film on a plurality of base materials at the same time, including a support unit, a vacuum chamber, a deposition source, and a low temperature evacuation section.

The support unit includes a rotation shaft and a support section that rotatably supports the plurality of base materials around the rotation shaft. The vacuum chamber includes a processing chamber that rotatably accommodates the support unit around the rotation shaft. The deposition source is provided inside the vacuum chamber. The low temperature evacuation section includes a low temperature condensation source provided on an upper surface of the vacuum chamber.

According to an embodiment of the present invention, there is provided a deposition method including accommodating a base material inside a vacuum chamber. The inside of the vacuum chamber is evacuated to a predetermined degree of vacuum by a low temperature condensation source that is provided opposed to the inside of the vacuum chamber. A first covering film is formed on a surface of the base material by a plasma CVD method in a state where communication between the low temperature condensation source and the inside of the vacuum chamber is shut off. A second covering film is formed on the surface of the base material by a vacuum vapor deposition method or a sputtering method in a state where the low temperature condensation source is in communication with the inside of the vacuum chamber.

### Best Modes for Carrying Out the Invention

According to an embodiment of the present invention, there is provided a deposition apparatus that forms a film on a plurality of base materials at the same time, including a support unit, a vacuum chamber, a deposition source, and a low temperature evacuation section.

The support unit includes a rotation shaft and a support section that rotatably supports the plurality of base materials around the rotation shaft. The vacuum chamber includes a processing chamber that rotatably accommodates the support unit around the rotation shaft. The deposition source is provided inside the vacuum chamber. The low temperature evacuation section includes a low temperature condensation source provided on an upper surface of the vacuum chamber.

In the deposition apparatus, the inside of the vacuum chamber is mainly evacuated by the low temperature evacuation section to a predetermined degree of vacuum. A coil plate (cryo panel) or a cryo coil in which a fluorocarbon refrigerant or a refrigerant such as liquid nitrogen and liquid helium circulates can be used for the low temperature condensation source. In the present invention, by placing the low temperature condensation source to face the inside of the vacuum chamber, an effective evacuation rate is increased and an evacuation time is reduced. In addition, since the low temperature evacuation section has a structure in which gas within the chamber is condensed and evacuated, it is possible to improve evacuation efficiency in an evacuation system having a large condensing load as compared to a gas-transportation-type evacuation mechanism such as a rotary pump, an oil diffusion pump, and a turbo molecular pump.

As described above, with the deposition apparatus, the evacuation time inside the vacuum chamber can be reduced. As a result, a cycle time of the apparatus can be reduced and productivity can be improved.

By placing the low temperature condensation source on an upper surface of the vacuum chamber, it becomes possible to place the deposition source on a surface of an inner circumferential sidewall of the vacuum chamber. As the deposition source, a sputtering target, a cathode for plasma CVD, or the like is appropriate. Instead of or in addition to the example above, the deposition source may be an evaporation source placed in an axial center portion of the support unit. In other words, various vacuum deposition methods such as a vacuum vapor deposition method, a sputtering method, and a plasma CVD method can be applied.

The support unit includes a rotation shaft and a support section that rotatably supports the plurality of base materials around the rotation shaft. The base material is formed with a film while rotating and revolving inside the vacuum chamber, with the result that a highly-uniform deposition on the surface of the base material becomes possible. In addition to a plate-shaped member such as a semiconductor wafer and a glass substrate, a molded body that is made of a plastic material and has a complicated three-dimensional shape can be used as the base material.

In the deposition apparatus, the low temperature evacuation section includes an opening for causing the processing chamber and the low temperature condensation source to communicate with each other, and the deposition apparatus further includes a valve mechanism for opening/closing the opening. Accordingly, an inside of the low temperature evacuation section is not exposed to an air atmosphere when, for example, the processing chamber is opened to the air atmosphere, with the result that it becomes possible to prevent the low temperature condensation source from being contaminated.

Further, by providing an auxiliary pump for evacuating the processing chamber in the deposition apparatus, the auxiliary pump assists an evacuation operation in the processing chamber by the low temperature evacuation section as a main pump, with the result that it becomes possible to further improve evacuation efficiency. The low temperature condensation source selectively discharges a condensing load such as an emitted gas represented by moisture, and the gas-transportation-type auxiliary pump evacuates a noncondensable process gas represented by Ar, N₂ and O₂, with the result that a processing atmosphere with high-quality vacuum can be realized.

On the other hand, according to an embodiment of the present invention, there is provided a deposition method including accommodating a base material inside a vacuum chamber. The inside of the vacuum chamber is evacuated to a predetermined degree of vacuum by a low temperature condensation source that is provided opposed to the inside of the vacuum chamber. A first covering film is formed on a surface of the base material by a plasma CVD method in a state where communication between the low temperature condensation source and the inside of the vacuum chamber is shut off. A second covering film is formed on the surface of the base material by a vacuum vapor deposition method or a sputtering method in a state where the low temperature condensation source is in communication with the inside of the vacuum chamber.

In the deposition method, vacuum evacuation by the low temperature condensation source is mainly used when the inside of the vacuum chamber is evacuated from an air atmosphere to a high degree of vacuum or when a deposition process under a high vacuum atmosphere as in a sputtering method is performed. Further, the communication between the low temperature condensation source and the inside of the vacuum chamber is shut off to prevent the low temperature condensation source from being contaminated during a deposition process in which there is a fear that a raw material gas or a plasma product will adhere to the low temperature condensation source as in a plasma CVD method. In this case, the inside of the vacuum chamber may be evacuated by the auxiliary pump prepared in addition to the low temperature condensation source.

### DRAWINGS

Hereinafter, embodiments of the present invention will be described based on the drawings.

FIG. 1 is a perspective view showing a schematic structure of a deposition apparatus according to an embodiment of the present invention;

FIG. 2 is a plan view showing the schematic structure of the deposition apparatus according to the embodiment of the present invention;

FIG. 3 is a side view showing the schematic structure of the deposition apparatus according to the embodiment of the present invention;

FIGS. 4A and B are plan views each showing a structure of a vacuum chamber of the deposition apparatus according to the embodiment of the present invention, in which FIG. 4(A) shows an opened state of a processing chamber, and FIG. 4(B) shows a hermetically-sealed state of the processing chamber;

FIG. 5 is a side view for explaining a structure of a support unit of the deposition apparatus according to the embodiment of the present invention; and

FIG. 6 is a cross-sectional view of an evacuation unit of the deposition apparatus according to the embodiment of the present invention.

### DETAILED DESCRIPTION

Hereinafter, an embodiment of the present invention will be described with reference to the drawings. In this embodiment, a description will be given taking, as an example, a batch-type deposition apparatus that sequentially deposits, using a resin molded body which constitutes a reflector of a headlight as a base material, a base film formed of a synthetic resin, a reflective film constituted of a vapor-deposited film or a sputtered film formed of aluminum, and a protective film formed of a synthetic resin on a surface of the base material.

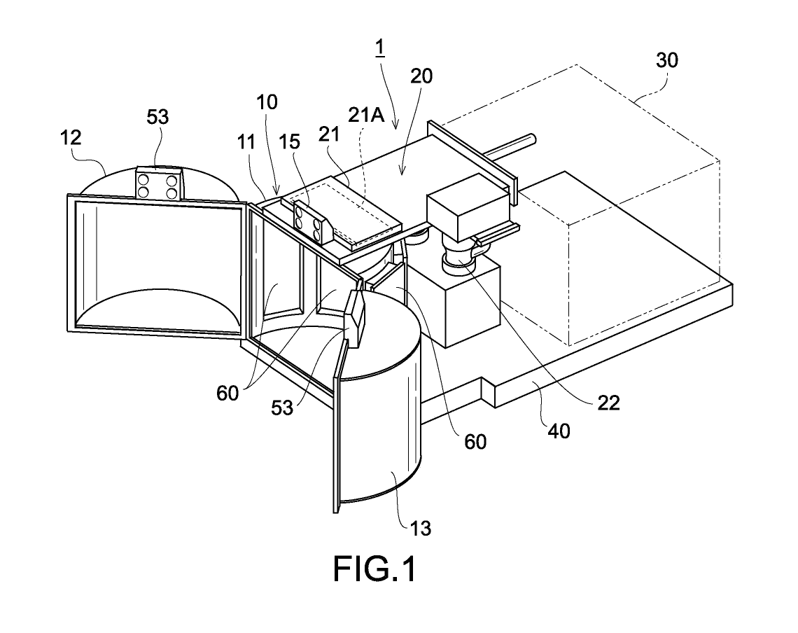

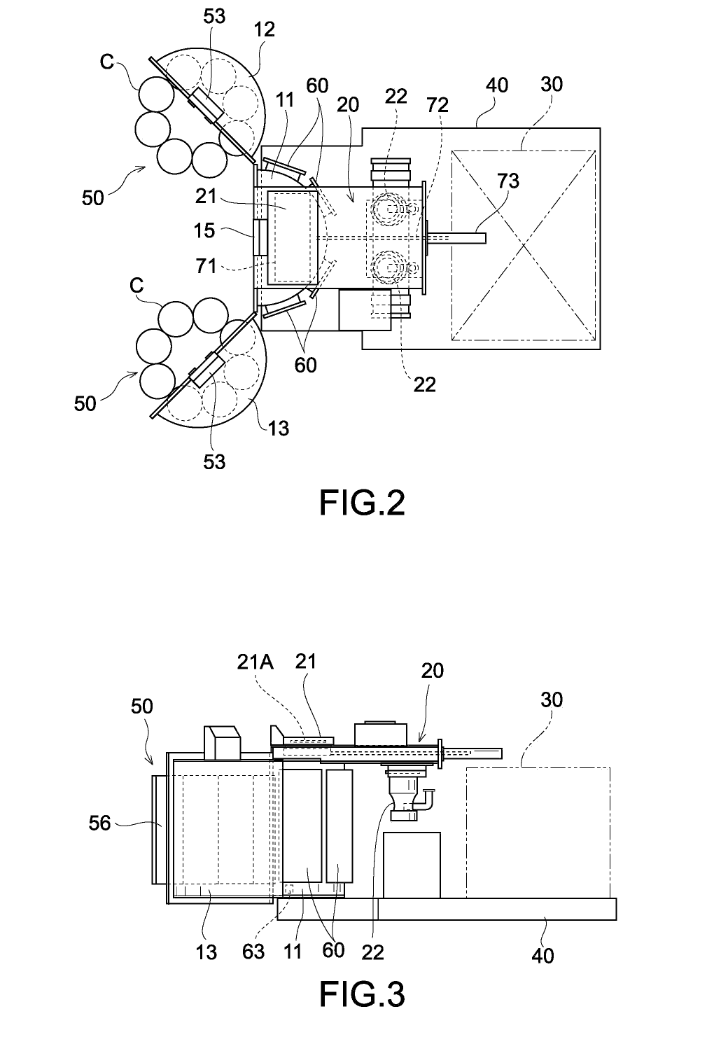

FIGS. 1 to 3 each show a schematic structure of a deposition apparatus 1 according to the embodiment of the present invention. FIG. 1 is a perspective view, FIG. 2 is a plan view, and FIG. 3 is a side view.

The deposition apparatus 1 includes a vacuum chamber 10, an evacuation unit 20 that evacuates an inside of the vacuum chamber 10, a control unit 30 for controlling various operations of the vacuum chamber 10 and the evacuation unit 20, and a common base 40 that commonly supports the vacuum chamber 10, the evacuation unit 20, the control unit 30.

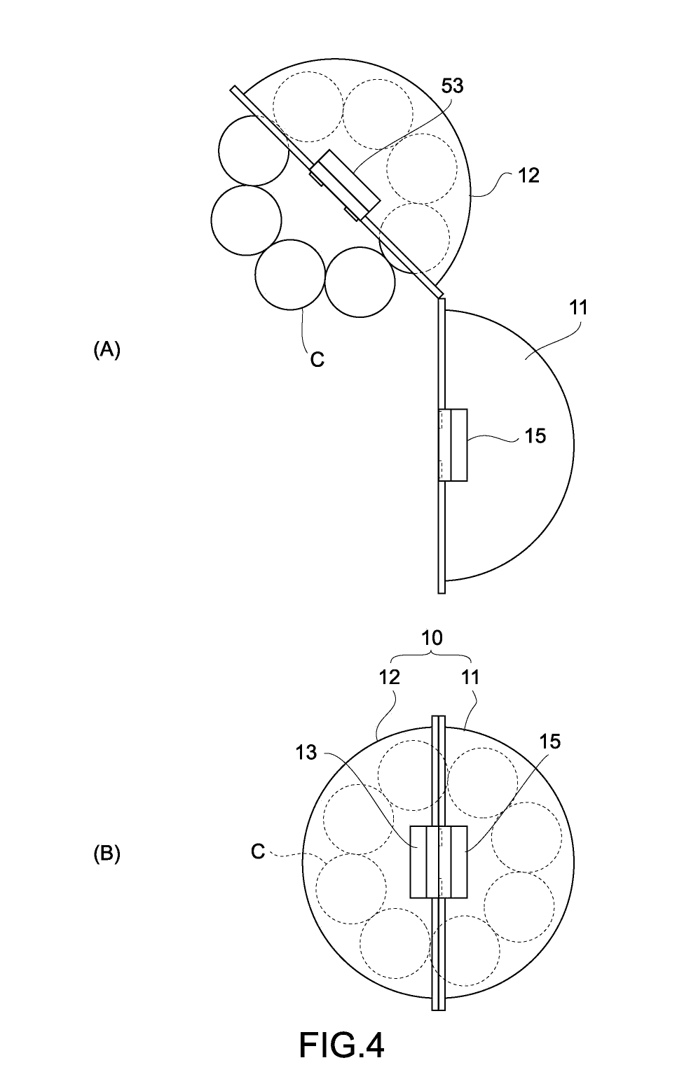

The vacuum chamber 10 includes a first vacuum chamber body 11 and a second vacuum chamber body 12. The first vacuum chamber body 11 is placed on the common base 40, and the second vacuum chamber body 12 is detachably attached to the first vacuum chamber body 11. FIG. 4 are plan views schematically showing a structure of the vacuum chamber 10.

In this embodiment, the vacuum chamber 10 has a cylindrical-shaped or polygonal column-shaped processing chamber 14 having a sealing structure (see, FIG. 4) formed inside. Each of the first vacuum chamber body 11 and the second vacuum chamber body 12 is formed in a half-moon shape in plan view bisected with a cross section along an axial direction of the vacuum chamber. The first vacuum chamber body 11 and the second vacuum chamber body 12 are mutually attached at one side edge portions thereof via a hinge, and the second vacuum chamber body 12 is rotatable with respect to the first vacuum chamber body 11 so that the first vacuum chamber body 11 can be opened/closed. It should be noted that although not shown, an appropriate sealing member is attached to a junction of the first vacuum chamber body 11 and the second vacuum chamber body 12.

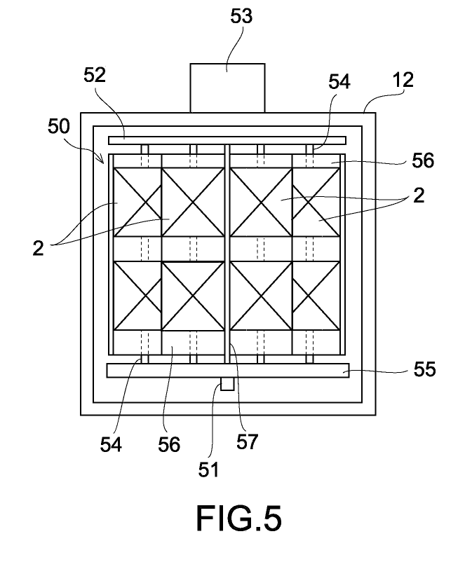

A support unit 50 for supporting a plurality of base materials 2 is installed inside the second vacuum chamber body 12. FIG. 5 is a side view showing a schematic structure of the support unit 50.

The support unit 50 includes a rotation shaft 51 and a support section 55 that rotatably supports the plurality of base materials 2 around the rotation shaft 51. The rotation shaft 51 is formed at a center portion of the support section 55 and connected to a driving section 63 which is provided on a bottom wall of the first vacuum chamber body 11 when the second vacuum chamber body 12 is combined with the first vacuum chamber body 11. The support unit 50 is rotatably supported inside the second vacuum chamber body 12 via an appropriate support (not shown).

In a circumference of the support section 55, a plurality of (in this embodiment, 8) support shafts 54 that are parallel to an axial direction of the rotation shaft 51 are arranged concyclically. These support shafts 54 are commonly supported at upper ends thereof by an upper support member 52. A plate member 56 is attached to each of the support shafts 54, and the plate members 56 support the plurality of base materials 2 along an axial direction of the support shafts 54. The support shaft 54 is configured to be rotatable (spinnable) around the axial direction by drive of the driving section 63. The support shaft 54 may be configured to rotate in sync with a rotation of the rotation shaft 51 or may be configured to rotate irrespective of the rotation of the rotation shaft 51. Alternatively, a mechanism in which the support shaft 54 rotates in sync with a rotation of the support unit 50 inside the vacuum chamber 10 may be employed. It should be noted that in FIGS. 2 and 4, 8 individual circles C that lie annularly and constitute the support unit 50 each represent a trajectory of a rotation of the plate member 56.

Attached to the support unit 50 is an evaporation source (deposition source or first deposition source) 57 for depositing films on the base materials 2. The evaporation source 57 is constituted of a resistance heating line extending from the support section 55 to the upper support member 52 at a position corresponding to a shaft center of the support unit 50. In the evaporation source 57, filaments for accommodating an evaporation material are formed at predetermined intervals in an axial direction. Aluminum or an alloy thereof is used for the evaporation material, though of course not limited thereto.

A power supply unit 15 is provided on an outer surface of an upper wall of the first vacuum chamber 11. The power supply unit 15 is provided at a position corresponding to a position of a power reception section 53 provided in the second vacuum chamber body 12 such that the power supply unit 15 and the power reception section 53 are coupled to each other when the vacuum chamber 10 is closed, as shown in FIG. 4(B). In this embodiment, the power supply unit 15 side and the power reception section 53 side are configured as a power feed terminal and a power reception terminal, respectively, and electric power required for the evaporation source 57 is supplied to the power reception section 53 when the vacuum chamber 10 is closed.

Further, the deposition apparatus 1 of this embodiment includes a third vacuum chamber body 13 having the same structure as the second vacuum chamber body 12. The third vacuum chamber body 13 is rotatably attached to a side edge portion of the first vacuum chamber body 11 which is opposite to the second vacuum chamber body 12 side while being detachable from the first vacuum chamber body 11. Accordingly, while one of the second vacuum chamber body 12 and the third vacuum chamber body 13 constitutes the vacuum chamber 10 in combination with the first vacuum chamber body 11 and performs predetermined deposition processes, processed base materials 2 are carried out from and unprocessed base materials 2 are carried into the other vacuum chamber body. It should be noted that the constituent parts of the second vacuum chamber body 12 and the third vacuum chamber body 13 that correspond to each other are denoted by the same symbols in the figures.

Next, an internal structure of the first vacuum chamber body 11 will be described.

A plurality of (in this embodiment, 4) cathode plates 60 are detachably attached to a surface of a sidewall of the first vacuum chamber body 11 at predetermined intervals. Each of the cathode plates 60 is configured as a sputtering target or a cathode for plasma CVD (deposition source or second deposition source). A selection on which of the sputtering target and the cathode for plasma CVD is to be used, a way of combining them, the number of cathode plates 60 to be used, an arrangement thereof, and the like are set as appropriate based on a type of material to be used for the deposition, a deposition form, and the like.

It should be noted that although not shown, a gas introducing tube for introducing predetermined process gasses (noble gas, reactive gas) required for sputtering or plasma CVD into the processing chamber 14 is provided in the first vacuum chamber body 11.

The evacuation unit 20 is provided at an upper portion of the first vacuum chamber 11. The evacuation unit 20 includes a low-temperature-condensation-type low temperature evacuation section 21 as a main pump and gas-transportation-type auxiliary pumps 22. Oil diffusing pumps are used as the auxiliary pumps 22, but turbo molecular pumps or rotary pumps may be used instead, for example. Although the number of auxiliary pumps 22 is not particularly limited, a pair of auxiliary pumps 22 are provided in this embodiment.

The low temperature evacuation section 21 includes a low temperature condensation source 21A such as a cryo panel and a cryo pump and a cooler (not shown) for cooling a refrigerant that circulates in the low temperature condensation source 21A. A fluorocarbon refrigerant, liquid nitrogen, or liquid helium is used as the refrigerant. The low temperature condensation source 21A is provided opposed to an inside (processing chamber 14) of the vacuum chamber 10. Particularly in this embodiment, the low temperature condensation source 21A is placed on an upper surface of the vacuum chamber 10 so as to oppose the upper support member 52 of the support unit 50.

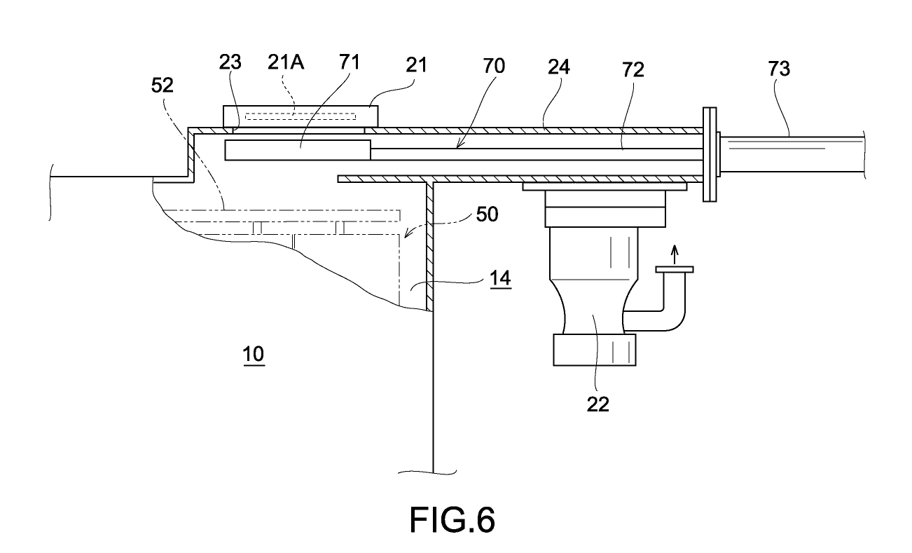

FIG. 6 is an enlarged view of a main part of FIG. 3. The low temperature evacuation section 21 includes an opening 23 for causing the processing chamber 14 and the low temperature condensation source 21A to communicate with each other. Further, a valve mechanism 70 for opening/closing the opening 23 is provided on a processing chamber 14 side. The valve mechanism 70 includes a valve body 71 that functions as a gate valve and has a seal surface to which a sealing member such as an o-ring (not shown) is attached, a driving shaft 72 attached to the valve body 71, and a driving section 73 that enables the driving shaft 72 to move in an axial direction and slightly move in a vertical direction in the figure which is orthogonal to the axial direction. As shown in FIG. 6, the valve body 71 selectively takes a first position at which the valve body 71 blocks the opening 23 and shuts off the communication between the processing chamber 14 and the low temperature condensation source 21A and a second position at which the valve body 71 opens the opening 23 and causes the processing chamber 14 and the low temperature condensation source 21A to communicate with each other.

The valve body 71 is provided inside a valve chamber 74 formed between the processing chamber 14 and the low temperature evacuation section 21. The valve chamber 74 is formed inside an evacuation channel 24 that extends from the upper portion of the first vacuum chamber body 11 toward a rear side (right-hand side in FIG. 6). The auxiliary pumps 22 are installed on a lower-surface side of the evacuation channel 24 between the first vacuum chamber body 11 and the driving section 73. The auxiliary pumps 22 evacuate the processing chamber 14 through the evacuation channel 24.

The control unit 30 includes various devices required for operating the deposition apparatus 1, such as a control computer, a power supply source, and an operation panel. By mounting the control unit 30 on the common base 40 together with the vacuum chamber 10, the apparatus can be provided as a single unit.

Next, a description will be given on an example of an operation of the deposition apparatus 1 structured as described above.

As shown in FIGS. 1 and 2, the second vacuum chamber body 12 and the third vacuum chamber body 13 are opened with respect to the first vacuum chamber body 11. Regarding the valve mechanism 70, the valve body 71 is at the second position such that the low temperature evacuation section 21 and the processing chamber 14 communicate with each other. After an unprocessed base material 2 is carried into the support unit 50 of the second vacuum chamber body 12, the second vacuum chamber body 12 is rotated to be coupled with the first vacuum chamber body 11. Accordingly, the processing chamber 14 of the vacuum chamber 10 is hermetically sealed.

After the processing chamber 14 is hermetically sealed, the auxiliary pumps 22 are firstly driven so that the processing chamber 14 and the low temperature evacuation section 21 are evacuated through the evacuation channel 24. Then, the refrigerant circulates in the low temperature condensation source 21A of the low temperature evacuation section 21, and the inside of the low temperature evacuation section 21 and the processing chamber 14 are evacuated to a predetermined level of vacuum (e.g., 10⁻² Pa).

In general, in vacuum evacuation in an air atmosphere or an environment where a large amount of emitted gas is present, a condensing load is dominant, and evacuation efficiency is higher in an evacuation method which utilizes a low temperature condensation of gas than in a gas-transportation-type evacuation method. In addition, an evacuation rate of a gas-transportation-type vacuum pump significantly changes depending on design of a vacuum evacuation diameter. For example, even when a vacuum pump having a nominal evacuation rate of 10,000 liter/sec is used, an actual evacuation rate (effective evacuation rate) may be lowered to 5,000 liter/sec depending on a length or a sectional area of an evacuation pipe.

In this regard, in this embodiment, the auxiliary pumps 22 roughly evacuate the processing chamber 14, and after the processing chamber 14 reaches a predetermined degree of vacuum (e.g., 1,000 Pa), the low temperature condensation source 21A takes charge in evacuating the processing chamber 14 to thus improve evacuation efficiency. By thus using the low temperature condensation source 21A as a main pump, evacuation efficiency in the processing chamber 14 is improved and an evacuation time is reduced as compared to the gas-transportation-type vacuum pump. As a result, it becomes possible to reduce a downtime cost of the apparatus and improve productivity. Moreover, since design of a vacuum evacuation system becomes easy, it becomes possible to improve a degree of freedom in structuring an apparatus and reduce design costs.

Further, according to this embodiment, since the low temperature condensation source 21A is provided at a position at which it faces the processing chamber 14, high evacuation efficiency of the processing chamber 14 can be secured. Moreover, since the low temperature condensation source 21A is provided on the upper surface of the processing chamber 14, a deposition means such as a sputtering target and a cathode for plasma CVD can be provided on the surface of the sidewall of the processing chamber 14.

After the processing chamber 14 reaches a predetermined degree of vacuum, a rotation and revolution of the base material 2 by the support unit 50 are initiated within the processing chamber 14. In this embodiment, plasma of argon, air, or nitrogen gas is generated in the processing chamber 14 to clean a surface of the base material 2 (bombard treatment) before a deposition process on the base material 2 is initiated. An appropriate cathode plate 60 configured as a cathode for plasma CVD can be used for generating the plasma. At this time, the valve body 71 of the valve mechanism 70 is at the second position at which the low temperature condensation source 21A is in communication with the processing chamber 14.

Subsequently, a base film (first covering film) is formed on the surface of the base material 2. In this process, a resin film is formed on the surface of the base material 2 by a plasma CVD (polymerization) method. A monomer gas of hexamethyldisiloxane (HMDSO) can be used as a raw-material gas, for example. In this case, a resin film formed of HMDSO is formed on the surface of the base material 2. By the base material 2 rotating and revolving in the processing chamber 14, the base film is uniformly formed on the surface of the base material 2.

In the base film formation process, in order to prevent the raw material gas or a plasma product generated in the processing chamber 14 from adhering to the low temperature condensation source 21A, the valve body 71 of the valve mechanism 70 is moved to the first position as shown in FIG. 6 to shut off the communication between the low temperature condensation source 21A and the processing chamber 14. Since the auxiliary pumps 22 operate constantly, the processing chamber 14 is evacuated by the auxiliary pumps 22 through the evacuation channel 24.

After the base film is formed on the base material 2, a reflective film (second covering film) is formed on the base film. A vacuum vapor deposition method or a sputtering method is used for forming the reflective film. In a case where the reflective film is formed by the vacuum vapor deposition method, the evaporation source 57 provided in the support unit 50 is used. On the other hand, in a case where the reflective film is formed by the sputtering method, the cathode plates 60 as sputtering cathodes provided on the surface of the sidewall of the processing chamber 14 are used. Aluminum or an alloy thereof is used for an evaporation material and a sputtering target. By the base material 2 rotating and revolving in the processing chamber 14, the reflective film is uniformly formed on the surface of the base material 2.

In the reflective film formation process, in order to maintain the processing chamber 14 at relatively-high vacuum, the valve body 71 of the valve mechanism 70 is moved to the second position to cause the processing chamber 14 and the low temperature condensation source 21A to communicate with each other.

After the reflective film is formed, a protective film (third covering film) is formed on the reflective film. In this process, a resin film is formed on the surface of the base material 2 by a plasma CVD (polymerization) method. A monomer gas of HMDSO can be used as a raw-material gas, for example. In this case, a resin film formed of HMDSO is formed on the surface of the base material 2. By a rotation and revolution of the base material 2 in the processing chamber 14, the protective film is uniformly formed on the surface of the base material 2.

In the protective film formation process, in order to prevent the raw material gas or a plasma product generated in the processing chamber 14 from adhering to the low temperature condensation source 21A, the valve body 71 of the valve mechanism 70 is moved to the first position as shown in FIG. 6 to shut off the communication between the low temperature condensation source 21A and the processing chamber 14. Since the auxiliary pumps 22 operate constantly, the processing chamber 14 is evacuated by the auxiliary pumps 22 through the evacuation channel 24.

Subsequently, after the protective film is formed on the base material 2, plasma of argon, air, or nitrogen gas is generated in the processing chamber 14 to treat the surface of the base material 2 (hydrophilic treatment). An appropriate cathode plate 60 configured as a cathode for plasma CVD can be used for generating the plasma. At this time, the valve body 71 of the valve mechanism 70 is at the second position at which the low temperature condensation source 21A is in communication with the processing chamber 14. With this surface treatment, a surface of the protective film is hydrophilized, and water drops and the like become difficult to be formed.

After the predetermined deposition processes on the base material 2 are completed, the processing chamber 14 is opened to an air atmosphere. After that, the first vacuum chamber body 11 and the second vacuum chamber body 12 are separated to open the processing chamber 14. Then, the processed base material 2 is carried out from the second vacuum chamber body 12. At this time, the valve body 71 of the valve mechanism 70 is at the first position shown in FIG. 6 to maintain a state where the communication between the processing chamber 14 and the low temperature condensation source 21A is shut off. Accordingly, a vacuum state inside the low temperature evacuation section 21 can be maintained.

Subsequently, the third vacuum chamber body 13 into which an unprocessed base material 2 has been carried is coupled to the first vacuum chamber body 11 to hermetically seal the processing chamber 14. Then, the processing chamber 14 is evacuated to a predetermined degree of vacuum. At this time, since the low temperature evacuation section 21 is maintained at a predetermined vacuum state by the valve mechanism 70, it becomes possible to reduce a time for rough evacuation by the auxiliary pumps 22 and the condensing load on the low temperature condensation source 21A. As a result, it becomes possible to reduce the evacuation time in the processing chamber 14.

In the processing chamber 14, films are formed on the base material 2 by the same procedure as described above. Meanwhile, an unprocessed base material 2 is carried into the second vacuum chamber body 12. After the films are formed and the third vacuum chamber body 13 is separated from the first vacuum chamber body 11, the second vacuum chamber body 12 is coupled with the first vacuum chamber body 11 to form the processing chamber 14 in which films are formed on the base material 2. Thereafter, the same operation is repeated.

According to this embodiment, the following effects can be obtained.

Since the evacuation unit 20 for evacuating the processing chamber 14 is constituted using the low temperature evacuation section 21 as a main pump, an evacuation time for evacuating the processing chamber 14 from an air atmosphere to a predetermined degree of vacuum can be reduced, with the result that it becomes possible to improve productivity. Such an effect is particularly advantageous in a batch-type deposition apparatus as in this embodiment.

The low temperature condensation source 21A selectively discharges the condensing load such as an emitted gas represented by moisture, and the gas-transportation type auxiliary pumps 22 discharge a noncondensable process gas represented by Ar, N₂, and O₂, with the result that a processing atmosphere with high-quality vacuum can be realized.

By structuring a vacuum evacuation system based on the low temperature evacuation section 21, design of a vacuum evacuation system becomes easy, with the result that it is possible to realize an improvement of a degree of freedom in apparatus design and a reduction in production costs. Moreover, a structure of the vacuum evacuation system can be made compact, thus resulting in a large contribution to a reduction in size and unitization of the apparatus.

By providing the valve mechanism 70 capable of shutting off the low temperature condensation source 21A from the processing chamber 14, it is possible to prevent the low temperature condensation source 21A from being contaminated when the processing chamber 14 is opened to the air atmosphere. In addition, it becomes possible to easily isolate the low temperature condensation source 21A from the processing chamber 14 in accordance with a process carried out in the processing chamber 14.

By providing the low temperature condensation source 21A at the upper portion of the vacuum chamber 10, a degree of freedom in design of the processing chamber 14 is improved, with the result that different types of deposition sources such as an evaporation source, a sputtering target, and a cathode for plasma CVD can be accommodated in the processing chamber 14. Accordingly, a deposition apparatus that is capable of flexibly supporting various processes can be structured.

Heretofore, the embodiment of the present invention has been described. However, the present invention is not limited to the above embodiment alone, and various modifications can of course be made without departing from the gist of the present invention.

For example, in the above embodiment, the description has been given using a reflector member of a headlight for an automobile as an example of the base material 2. However, the present invention is not limited thereto and is also applicable to a deposition of an article having a three-dimensional shape, such as an emblem and various frame members, as well as an article having a two-dimensional deposition surface, such as a semiconductor wafer and a glass substrate.

Further, although the example in which the base film, the reflective film, and the protective film are laminated in the stated order on the surface of the base material 2 has been described in the embodiment described above, the deposition form is not limited to the above example. For example, a multilayer structure constituted of different types of sputtering films can also be employed.

1. A deposition apparatus that forms a film on a plurality of base materials at the same time, comprising:
a support unit including a rotation shaft and a support section that rotatably supports the plurality of base materials around the rotation shaft;
a vacuum chamber including a cylindrical-shaped or polygonal-column-shaped processing chamber formed therein;
a deposition source provided on an inner circumferential surface of the vacuum chamber;
a low temperature evacuation section including a low temperature condensation source provided on an upper surface of the vacuum chamber; and
a gas-transportation-type auxiliary pump provided to evacuate the vacuum chamber.

2. The deposition apparatus according to claim 1,
wherein the deposition source is at least one of a sputtering target and a cathode for plasma CVD.

3. The deposition apparatus according to claim 1 or 2, further comprising
an evaporation source provided at an axial center portion of the support unit.

4. The deposition apparatus according to claim 1, further comprising
evaporation source provided at an axial center portion of the support unit,
wherein the deposition source is at least one of a sputtering target and a cathode for plasma CVD that is provided on a surface of a sidewall of the processing chamber.

5. The deposition apparatus according to claim 1,
wherein the low temperature evacuation section includes an opening for causing the processing chamber and the low temperature condensation source to be in communication with each other,
the deposition apparatus further comprising
a valve mechanism including a valve body for opening/closing the opening.

6. The deposition apparatus according to claim 5,
wherein the auxiliary pump is provided in an evacuation channel connected to an upper portion of the vacuum chamber, and a valve body of the valve body is provided within the evacuation channel.

7. The deposition apparatus according to claim 1,
wherein the vacuum chamber includes a first vacuum chamber body in which the low temperature evacuation section is provided and a second vacuum chamber body that is detachably attached to the first vacuum chamber body and holds the support unit.

8. A deposition method, comprising:
exposing an vacuum chamber to an air atmosphere to accommodate a plurality of base materials inside the vacuum chamber;
evacuating, after hermetically sealing the vacuum chamber and roughly evacuating the vacuum chamber by an gas-transportation-type auxiliary pump, the inside of the vacuum chamber to a predetermined degree of vacuum by a low temperature condensation source that is provided opposed to the inside of the vacuum chamber;
forming a first covering film on a surface of each of the plurality of base materials by a cathode for plasma CVD that is provided on a side wall of the vacuum chamber in a state where communication between the low temperature condensation source and the inside of the vacuum chamber is shut off and the auxiliary pump is driven, while using the auxiliary pump and rotating the plurality of base materials about the rotation shaft; and
forming a second covering film on the surface of each of the plurality of base materials by a deposition source that is provided on an axial center of the rotation shaft or a cathode for sputtering that is provided on the side wall of the vacuum chamber in a state where the low temperature condensation source is in communication with the inside of the vacuum chamber, while using the low temperature condensation source and the auxiliary pump and rotating the plurality of base materials around the rotation shaft.

9. The deposition method according to claim 8, further comprising
plasma-cleaning, before the formation of the first covering film, the surface of each of the base materials in a state where the low temperature condensation source is in communication with the inside of the vacuum chamber.

10. The deposition method according to claim 8, further comprising
forming, after forming the second covering film on the surface of the base material, a third covering film on the surface of each of the base materials by the plasma CVD method in a state where the communication between the low temperature condensation source and the inside of the vacuum chamber is shut off.

11. The deposition method according to claim 10, further comprising
subjecting, after forming the third covering film on the surface of each of the base materials, the surface of each of the base materials to a plasma treatment in a state where the low temperature condensation source is in communication with the inside of the vacuum chamber.

12. The deposition method according to claim 8,
wherein the accommodation of the base materials inside the vacuum chamber includes maintaining the state where the communication between the low temperature condensation source and the inside of the vacuum chamber is shut off.

13. The deposition apparatus according to claim 1,
wherein the vacuum chamber includes a first vacuum chamber body in which the deposition source is provided and a second vacuum chamber body that rotatably holds the support unit around the rotation shaft and opens and closes with respect to the first vacuum chamber body, and when the second vacuum chamber body is opened with respect to the first vacuum chamber, an inside of the vacuum chamber is exposed to an air atmosphere.
